(19) United States
(12) Patent Application Publication
(10) Pub. No.: US 2024/0146285 A1
(43) Pub. Date: May 2, 2024

(54) META-STABILITY-FREE TWO-CLOCK-DOMAIN SYNCHRONOUS LATCH

(71) Applicant: VIETTEL GROUP, Ha Noi City (VN)

(72) Inventors: Thai Ha Le, Ha Noi City (VN); Ha My Bui, Ha Noi City (VN); Anh Tuan Khong, Vinh Phuc Province (VN)

(73) Assignee: VIETTEL GROUP, Ha Noi City (VN)

(21) Appl. No.: 18/458,821

(22) Filed: Aug. 30, 2023

(30) Foreign Application Priority Data
Oct. 31, 2022 (VN) 1-2022-07069

(51) Int. Cl. H03K 3/037; G01R 31/3185

(52) U.S. Cl. CPC H03K 3/037; G01R 31/318536; G01R 31/318541; G01R 31/318552

(57) ABSTRACT

Described is a design to synchronize and prevent any clock timing issues associated with two clock domain crossing (CDC) in Design for Testing (DFT) and other CDC applications. In order to avoid any meta-stability issues associated with the sensitive edges of the two clock domains, the synchronization scheme splits the incoming data of the first clock domain into three branches, from which a finite state machine is to choose the correct branch for data transfer to the second clock domain. The selected branch will be the ‘safe’ one that guarantees there will be no timing issue at the second clock domain. This methodology can be applied in IC design that needs to optimize area and performance.

### FIELD OF INVENTION

The invention presents a two-clock-domain synchronous latch to the replace traditional asynchronous lockup latch to deal with the phase-sensitive between two clock domains and to have the whole combined chain (between the two clock domains) to be timing analyzed. Therefore, the timing of the whole design is guaranteed both in the static-timing analysis and is free from the meta-stability issue.

### BACKGROUND OF THE INVENTION

Clock domain crossing (CDC) is a major challenge in SoC design. The CDC occurs whenever data is transferred from a flop driven by one clock to a flop driven by another clock. Two clocks can be synchronous or asynchronous to each other. Designers use handshake or FIFO to resolve this problem. In Design for Testing (DFT) design, these well-known techniques make the circuit more complicated and these added circuits are not friendly to the Automatic Test Pattern Generation (ATPG) scheme. In addition, the meta-stability issue makes the delay of the synchronization circuits to be potentially one-cycle shifted. As a consequence, the ATPG scheme can not be fixed. This uncertainty creates problems in the DFT implementation and tests.

### RELATED APPLICATION

DFT design is a significant flow in System on Chip (SoC) design. The manufacturing test process ensures high-quality integrated circuits by screening out devices with manufacturing defects. There are two purposes of DFT. First, it creates a scan chain circuit to control and observe manufacturing faults (power or ground shorts, open interconnect on the die caused by dust particles, short-circuited source or drain on the transistor, caused by metal spike-through).

The scan chain should not affect the main function of the chip. Second, DFT creates test patterns for automated test equipment (ATE).

In scan design, commonly, the scan clock is based on a functional clock. However, some designs have more than one clock. It is complex if there are many blocks and asynchronous domains. This problem causes increasing the number of chains, area, and power consumption. To merge chains of some clock domains, the conventional asynchronous lockup latch is used. This method is commonly supported by electronic design automation (EDA) tools. However, it is impossible to guarantee the timing right before and right after the asynchronous latches. It relaxes hold time for the first flop of the second clock domain but there is no way to check timing at this path.

In addition, the meta-stability issue can happen when the active edges of both clock domains are close to each other. In order to avoid this problem, a scheme of three branches is introduced to select the safe one for the meta-stability issue. All three branches are to synchronize the two clock domains but not all of them are always safe from the meta-stability issue. The proposed scheme is to select the meta-stability-free branch among the three ones. And the selected branch is fixed for the whole operating time. The new selection is restarted after the reset action.

The proposed two-clock-domain synchronous latch is free from the CDC and the meta-stability issues.

### SUMMARY OF THE INVENTION

To conquer the disadvantage of asynchronous latches in the CDC scheme, especially in the two-clock domain combination flow in the DFT design, the invention provides a two-clock-domain synchronous latch module instead in replacement to a regular lockup latch. This module allows two clock domains to handshake and is free from the meta-stability issue.

### BRIEF DESCRIPTION OF THE DRAWINGS

FIG. 1 illustrates the connection of the asynchronous lockup latch with two clock domains CLK1 and CLK2

FIG. 1A illustrates the meta-stability when the active edges of CLK1 and CLK2 are close

FIG. 2 illustrates the two-clock-domain synchronous latch between two clock domains CLK1 and CLK2

FIG. 2A illustrates the schematic of the synchronous latch

FIG. 2B illustrates the state machine of the synchronous latch

FIG. 2C illustrates the data signal compared to CLK1 and CLK2

### DETAILED DESCRIPTION OF THE PREFERRED EMBODIMENTS

A conventional solution to decrease scan chain number is merging chains of two or some scan clock domains. It uses an asynchronous lockup latch to connect between two clock domains as shown in FIG. 1. Data from CLK1 goes through the asynchronous lockup latch before CLK2. The asynchronous lockup latch relaxes hold time for the FF2 flip-flop. The advantage of using a lockup latch is simple and is supported in the design flow of synthesis tools. However, there are two points needed to be considered. First, the asynchronous lockup latch cannot thoroughly resolve the timing problem of the asynchronous path. If the active edge of CLK1 is close to CLK2, the meta-stability state can occur. FIG. 1A describes this phenomenon. In FIG. 1A, the rising edge of CLK2 is close to the active edge of the asynchronous lockup latch. The hold time requirement is too short for a stable signal. Second, because of the asynchronous domain, the static timing analysis (STA) tool cannot check the timing for this path. The physical design tool does not place the asynchronous lockup latch close to the FF2 flip-flop. In some actual cases, the scan chain occurs timing violation.

The purpose of this patent is to resolve the disadvantages mentioned above when using the asynchronous lockup latch and thence improve the performance and ensure scan chains work properly. In this patent, the method of replacing the asynchronous lockup latch with a synchronous latch allows two clock domains to synchronize and balance. The two-clock-domain synchronous latch can resolve two disadvantages of the latch: the meta-stability of data when two active edges are too close. The behavior of the synchronizer and standard cell is the same, therefore, ensure timing and position. Thus, this one validates the DFT circuit works with desired frequency.

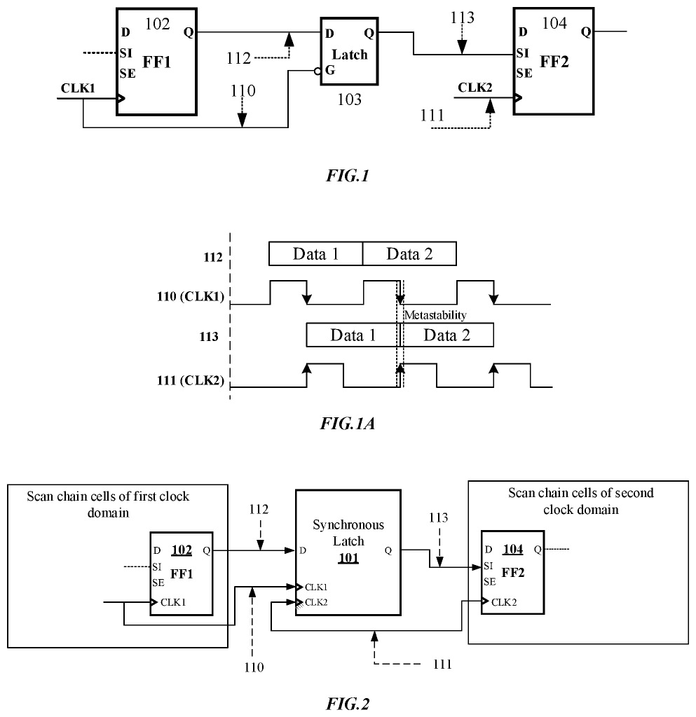

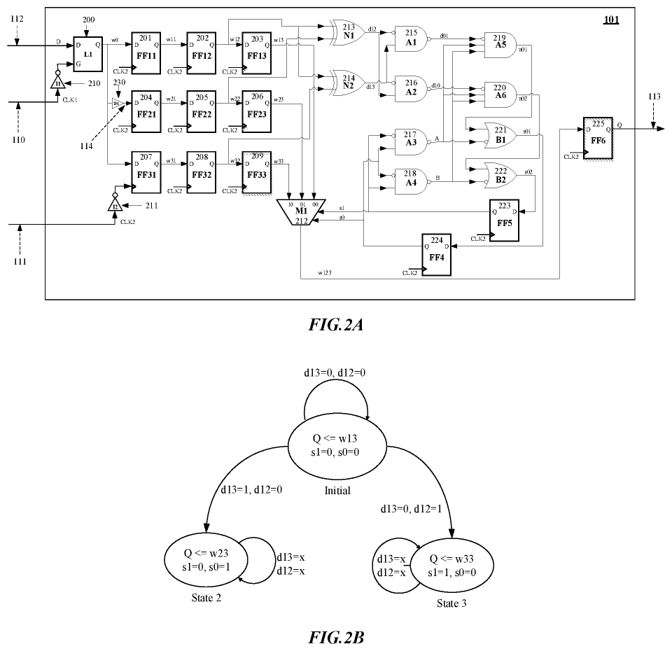

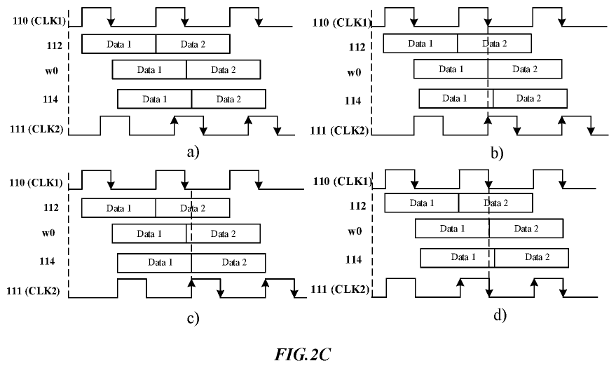

The synchronous latch has new architecture compared to the conventional lockup latch in the CLK2 domain. Logical circuit in 101 synchronizes two clock domains CLK1 and CLK2. FIG. 2 illustrates the architecture of the synchronous latch and connection between two flip-flops. The circuit includes three inputs and one output. Signals include: Clock of first domain 110; Clock of second domain 111; 112 is the last signal of the first clock domain. It goes to 101 circuit to synchronize with the second clock domain; 113 is the output of 101. This signal goes to the first flip-flop of the second clock domain. It is synchronized with the CLK2 domain.

The synchronous latch 101 resolves two problems: first is the unstable state when the active edge of two clock domains is too close. Second, this circuit ensures all paths are checked for timing. Moreover, the distance of cells in 101 is restricted so there are no timing violations at scan paths.

FIG. 2A describes the schematic of two-clock-domain synchronous latch 101. The input signal is 112. The output signal is 113. 110 and 111 are clock signals. Signal 112 synchronized with 110 (CLK1) is converted to 113. 113 is the signal of the second clock domain (CLK2). Signal 112 comes to the D input of a latch 200 (L1) and has a w0 output. Clock 110 (CLK1) is inverted by inverter 210 (I1) before going to 200. Therefore, the w0 signal is 112 signal but delayed a half cycle of the CLK1 clock.

After that, the w0 signal is divided into three paths:

The first path has three flip-flops 201 (FF11), 202 (FF12), and 203 (FF13). This one works with 111 clock (CLK2).

The second path has three flip-flops 204 (FF21), 205 (FF22), and 206 (FF23). The input is delayed by buffer 230 (D1). This buffer delays w0 about 5% of the clock cycle. This one works with 111 clock (CLK2).

The third path is delayed 50% of the clock cycle because of the inverted clock. It includes three flip-flops 207 (FF31), 208 (FF32), and 209 (FF33). w0 signal is synchronized with the inverted clock at flip-flop 207. This path has maximum latency compared to the two paths above.

Two signals s1 and s0 from 223 (FF5) and 224 (FF4) flip-flop will choose one of the three outputs (w13, w23, w33) of three paths. These three signals go through the multiplexer 212 (M1). Depending on s1 and s0, the output of 212 is w123 and goes to the last flip-flop 225 before going out to signal 113.
If (s1,s0)=(0,0) then w123 is assigned to w13 (first path)
If (s1,s0)=(0,1) then w123 is assigned to w23 (second path)
If (s1,s0)=(1,0) then w123 is assigned to w33 (third path)
Case (s1,s0)=(0,0) never happens

There are some expressions:

d12=w12XORw22

d13=w12XORw32

A=s[1:0]XOR[01]

B=s[1:0]XOR[10]

d01=[d12d13]XOR[01]

d10=[d12d13]XOR[10]

[s02,s01]=A̅.[01]+B̅.[10]+A.B.(d̅0̅1̅.[01]+d̅1̅0̅.[10])

FIG. 2B illustrates the state machine of the 101 circuit. In the initial state, the output is assigned to w13. s1 and s0 equal 0. If d12 and d13 still equal 0, this state keeps stable. If d13=1 and d12=0 (w12 not equal w32) then the second path is chosen. It ensures there is no meta-stability. Then d13 and d12 do not affect the future state. This stage does not change in the future. The third state is similar to the second state but when d13=0 and d12=1. Signal 113 is assigned to the third path. The case d13=1 and d12=1 does not occur because w12, w22, and w32 is binary value.

FIG. 2C describes signal 112 and clock 110 (CLK1), and 111 (CLK2). A basic principle of the patent is creating three paths with differential delay, then depending on the edge position of CLK1 and CLK2 choosing one of three paths. FIG. 2C(a) is a normal case when CLK2 delays a sufficient amount of timing compared to CLK1 to ensure stability in capturing data 112. FIG. 2C(b) illustrates the active edge of CLK2 closing to CLK1 of block 200 (falling edge). At this time, 101 decides to choose the second or third path because the first path is unstable.

FIG. 2C(c) illustrates the unstable state when signal 114 is too close to the active edge of clock CLK2 (rising edge). The third path will be chosen. FIG. 2C(d) describes the case the second path is chosen. The falling edge of CLK1 and CLK2 causes meta-stability. Signal 114 is enough to ensure stable data.

1. A two-clock-domain synchronous latch used for DFT (design for test) includes:
a clock signal of a first clock domain;
a clock signal of a second clock domain;
an input signal that is a last signal of the clock signal of the first clock domain will be synchronized with the second clock domain by the synchronous latch;
an output signal that is a first signal of the clock signal of the second clock domain.

2. A two-clock-domain synchronous latch used for DFT (design for test) according to claim 1, wherein:
the input signal goes to a latch (L1) that an output pin is w0; the clock signal of the first clock domain is inverted by an inverter before goes to the latch; for that reason, w0 is the input signal but is delayed a half of the clock signal of the first clock cycle.

3. A two-clock-domain synchronous latch used for DFT (design for test) according to claim 2, wherein:
w0 signal is divided into three paths; there are three flops in each path;
the first path works with a second clock (CLK2);
the input of the second path is delayed by a buffer (D1); this buffer delays w0 about 5% of the clock cycle; working with the second clock (CLK2);
the third path is delayed 50% of the clock cycle because of the inverted clock. w0 signal is synchronized with the inverted clock at a flip-flop, wherein path has maximum latency compared to the two paths above.
